(19) United States
(12) Patent Application Publication
(10) Pub. No.: US 2014/0261690 A1
(43) Pub. Date: Sep. 18, 2014

(54) INTERMEDIATE BAND SOLAR CELLS WITH DILUTE GROUP III-V NITRIDES

(71) Applicant: ERNEST ORLANDO LAWRENCE BERKELEY NATIONAL LABORATORY, Berkeley, CA (US)

(72) Inventors: Wladyslaw Walukiewicz, Kensington, CA (US); Kin Man Yu, Lafayette, CA (US)

(73) Assignee: Ernest Orlando Lawrence Berkeley National Laboratory, Berkeley, CA (US)

(21) Appl. No.: 13/844,442

(22) Filed: Mar. 15, 2013

(51) Int. Cl. H01L 31/0304; H01L 31/18

(52) U.S. Cl. CPC H01L 31/03048; H01L 31/1856
USPC 136/262; 438/93

(57) ABSTRACT

A single junction solar cell may be manufactured with a material having multiple bands. That is, a single semiconductor with several absorption edges that absorb photons from different parts of the solar spectrum may be constructed. The different absorption edges may be created by splitting a conduction band of the solar cell material into multiple intermediate sub-bands. The solar cell may include a photovoltaic material deposited on a substrate, in which the photovoltaic material is a III-V semiconductor alloy, such as AlGaNAs, AlGaAsNSb, or AlInGaNAsBi.

### GOVERNMENT SUPPORT STATEMENT

This invention was made with government support under Contract No. DE-AC02-05CH11231 awarded by the U.S. Department of Energy. The government has certain rights in the invention.

### FIELD OF THE DISCLOSURE

The instant disclosure relates to solar cells. More specifically, this disclosure relates to materials for solar cells.

### BACKGROUND

Solar cells are semiconductor devices for converting radiant energy of sunlight into electrical energy. Conversion of sunlight into electrical energy includes absorption of photons into a semiconductor material, generation and separation of positive and negative charges by the photon creating a voltage in the solar cell, and collection and transfer of the electrical charges through terminals coupled to the semiconductor material.

Conventional solar cells include a p-n junction, having a p-type material stacked on an n-type material. However, conventional solar cells have a low efficiency, often reaching only 30%. The limited efficiency of solar cells is due to the energy gap between a valence band and a conduction band of the solar cell. A solar cell only generates energy by absorbing photons with an energy level exceeding the energy gap of the solar cell. Photons from light impinging on the solar cell with an energy below the energy bandgap are not absorbed. These non-absorbed photos represent a large amount of light that could otherwise be converted to electrical energy.

One conventional solution is to improve efficiencies of solar cells by using stacks of p-n junctions. Each p-n junction may be formed with semiconductors with different energy gaps that are sensitive to photons of different energy. This concept has been realized in multi-junction or tandem solar cells such as GaAs/GaInP double junction or Ge/GaAs/GaInP triple junction cells. Power conversion efficiencies exceeding 40% are possible in multi-junction solar cells. However, the complexity of the design and high fabrication costs make the use of multi-junction solar cells unappealing for mass market consumption.

Another approach to improve the efficiency of solar cells is based on use of multiband semiconductors. It has been postulated that instead of using several semiconductors with different band gaps, a single semiconductor may be engineered with several absorption edges that absorb photons from different parts of the solar spectrum. The most important advantage of this design of high efficiency solar cells is that they require only a single p-n junction considerably simplifying the cell design and lowering the production costs.

Practical realization of a multiband semiconductor that could be used for solar cells has turned out to be extremely difficult. There were several attempts to intentionally introduce large concentrations of impurities or defects that would form an additional narrow band in the band gap of a standard semiconductor such as Si or GaAs. These attempts were not successful as the impurities and defects changed the key electrical properties of the materials making preparation of properly operating solar cells impossible.

### SUMMARY

A single junction solar cell may be manufactured with a material having multiple bands. That is, a single semiconductor may be constructed with several absorption edges that absorb photons from different parts of the solar spectrum. The different absorption edges may be created by splitting a conduction band of the solar cell material into multiple intermediate sub-bands. Such solar cells may be termed intermediate band solar cells (IBSCs).

IBSCs have a high efficiency and have simple cell designs with low production costs. Calculated power conversion efficiencies show IBSCs can achieve up to 63% and 72% for IBSCs fabricated using materials with optimized three and four energy bands, respectively. One material for IBSCs includes materials engineered with band anti-crossing in highly mismatched alloys (HMAs). In particular, III-V semiconductor alloys may be manufactured with a multiband structure suitable for IBSCs.

According to one embodiment, an intermediate band solar cell may include a substrate and a photovoltaic material formed on the substrate. The photovoltaic material may include a III-V semiconductor alloy having intermediate energy bands, such as an AlGaAsN alloy.

In certain embodiments, the intermediate band solar cell may also include a blocking layer on both sides of the photovoltaic material to electrically isolate the intermediate band. The blocking layer may comprise III-V semiconductor alloys such as AlGaAs.

According to another embodiment, an apparatus may include a first junction having a first material and a second material. The first material and the second material may include a III-V semiconductor alloy with an intermediate energy band, such as an AlGaAsN alloy. The first material may be p-type, and the second material may be n-type.

According to yet another embodiment, a method may include forming a photovoltaic material on a substrate, wherein forming the photovoltaic material comprises forming a photovoltaic material with an impurity to split a conduction band of the photovoltaic material into two intermediate sub-bands, and wherein forming the photovoltaic material comprises forming an AlGaAsN alloy.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features that are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the disclosed system and methods, reference is now made to the following descriptions taken in conjunction with the accompanying drawings.

FIG. 1 is a block diagram illustrating a semiconductor material with intermediate bands according to one embodiment of the disclosure.

FIG. 2 is a graph illustrating energy positions of direct optical gap E_{M} of AlGaAs alloy as a function of AlAs composition according to one embodiment of the disclosure.

FIG. 3 is a graph illustrating a band structure of Al_{0.4}Ga_{0.6}N_{0.02}As_{0.98} showing the structuring of the conduction band according to one embodiment of the disclosure.

FIG. 4 is a graph illustrating calculated mole fractions of GaN and GaSb for a Al_{z}Ga_{1-z}As_{1-x-y}NₓSb_{y} lattice matched to GaAs for different AlAs mole fractions according to one embodiment of the disclosure.

FIG. 5 is a block diagram illustrating a solar cell with first junction formed between p and n-type doped layers within an AlₓGa₁₋ₓN_{y}As_{1-y} absorber, in which the absorber has an intermediate band according to one embodiment of the disclosure.

### DETAILED DESCRIPTION

A photovoltaic device, solar cell, or intermediate band solar cell (IBSC) may have improved solar power conversion efficiency when a material of the solar cell has multiple band gaps. When the material has multiple band gaps, additional bands in the band gap serve as energy steps for transferring electrons from a valance band of the material to a conduction band of the material. Conventionally, when a photon strikes a material in a solar cell, the photon must have an energy exceeding the energy gap between the valence band and the conduction band of the material to create current in the material. The intermediate bands allow photons with smaller energies to excite electrons to intermediate levels, where another photon may excite the electron from the intermediate level to the conduction band. Thus, materials with intermediate band gaps are able to convert photons of a wider range of energies into current, and have a higher solar power conversion efficiency.

FIG. 1 is a block diagram illustrating a semiconductor material with intermediate bands. An energy diagram for a material may include a valence band 102 of electrons and a conduction band 104 of electrons. A photon 112 of sufficient energy to overcome an energy bandgap, E_{G}, equal to a difference in energy between the valence band 102, E_{V}, and the conduction band 104, E_{C}, may promote an electron from the valence band 102 to the conduction band 104. Intermediate band 106 may be present in the material between the valence band 102 and the conduction band 104. A photon 114 with an energy smaller than E_{G}, but larger than a difference in energy between the valence band 102, E_{V}, and the intermediate band 106, E_{I}, may promote an electron from the valence band 102 to the intermediate band 106. A second photon 116 may promote the electron from the intermediate band 106 to the conduction band 104.

Alloying semiconductor materials allows the optical and electronic properties of a semiconductor to be engineered by adding small amounts of alloying materials. Certain semiconductors, known as highly mismatched alloys (HMA), undergo a dramatic change in their optical and electrical properties upon the addition of as little as a few percent of an alloying species. A band anti-crossing (BAC) model may take into account an interaction of the impurity species, such as an additive, with a host crystal, such as a semiconductor alloy. Although electrically neutral, these impurities introduce localized states that undergo an anti-crossing interaction with the delocalized states of the host crystal. When the impurity species has a much greater electronegativity than that of the host anion, the defect states of the impurity atoms are often located near the conduction band edge of the host. Electrons may be localized near the impurity sites, and the s-like electron states may interact. The interaction causes the conduction band to split into two sub-bands, a higher E₊ sub-band and a lower E₋ sub-band.

In one embodiment, a material with intermediate bands may be created by forming III-V semiconductor alloys that are highly mismatched alloys (HMAs). In HMAs when the energy level of the impurity atoms lie below the conduction band of the host compound, anti-crossing interactions of the impurity states and the conduction band states create a narrow band (E₋) below the original impurity level position and push the conduction band up (E₊).

For example, aluminum-gallium-arsenide (AlGaAs) ternary alloys having intermediate bands may be created with nitrogen (N) substitution in the arsenide (As) sub-lattice in alloys with aluminum-arsenide (AlAs) mole fractions greater than 35%. FIG. 2 is a graph illustrating energy positions of direct optical gap E_{M} of AlGaAs alloy as a function of AlAs composition according to one embodiment of the disclosure. FIG. 2 shows energy positions of direct optical gap E_{M} of AlGaAs alloy as a function of AlAs composition plotted together with indirect transitions Eₓ and E_{L} and the N level E_{N}. The E₋ and E₊ positions as a function of N composition due to band anti-crossing are also calculated and also shown in FIG. 2. When the AlAs mole fraction is larger than 35%, the N level, E_{N}, lies below the conduction band.

In one embodiment, the material for a solar cell may be AlₓGa₁₋ₓN_{y}As_{1-y}, where x is between approximately 0.3 and approximately 0.5 and y is between approximately 0 and approximately 0.05, such as Al_{0.4}Ga_{0.6}N_{0.02}As_{0.98}. FIG. 3 is a graph illustrating a band structure of Al_{0.4}Ga_{0.6}N_{0.02}As_{0.98} showing the structuring of the conduction band according to one embodiment of the disclosure. FIG. 3 shows the calculated band structure of a Al_{0.4}Ga_{0.6}N_{0.02}As_{0.98} showing the re-structuring of the conduction band. Substitution of N in the As sub-lattice splits the original conduction band of the material into two intermediate sub-bands. A higher intermediate sub-band is marked E₊, and a lower intermediate sub-band is marked E₋. With the E₊ and E₋ sub-band split of Al_{0.4}Ga_{0.6}N_{0.02}As_{0.98}, incoming light with photons with energy larger than the three absorption edges, 0.61, 1.59 and 2.22 eV, may be efficiently absorbed. Materials, such as this N-doped AlGaAs alloy with three optical transitions may be well suited for the fabrication of solar cells, such as intermediate band solar cells (IBSCs).

Lattice mismatch between AlAs and GaAs alloys may be as small as 0.124%. Thus, AlGaNAs alloys may be a close lattice match with GaAs. Lattice matching between the AlGaNAs alloy and GaAs may be improved with additions to the AlGaNAs material. For example, lattice-matched IBSCs may be fabricated using AlGaNAs alloys with an addition of Sb in the anion sub-lattice. FIG. 4 is a graph illustrating calculated mole fractions of GaN and GaSb for a Al_{z}Ga_{1-z}As_{1-x-y}NₓSb_{y} lattice matched to GaAs for different AlAs mole fractions according to one embodiment of the disclosure. FIG. 4 shows mole fractions of GaN (x) and GaSb (y) for a Al_{z}Ga_{1-z}As_{1-x-y}NₓSb_{y} lattice matched to GaAs for different AlAs (z) mole fractions. For a material with an electronic structure similar to that of FIG. 3, a value of approximately 1-6%, or approximately 4%, of Sb may be used to lattice match the Al_{z}Ga_{1-z}As_{1-x-y}NₓSb_{y} material with GaAs. For example, a material may comprise an alloy of Al_{z}Ga_{1-z}As_{1-x-y}NₓSb_{y}, in which z is between approximately 0.3 and approximately 0.5, x is between approximately 0 and approximately 0.05, and y is between approximately 0.01 and approximately 0.06.

In another embodiment, lattice matching of AlGaNAs alloys may be achieved through addition of Bi and In to the anion and cation sub-lattices, respectively. For example, a material for IBSCs may comprise an alloy of Al_{z}In_{w}Ga_{1-z-w}NₓAs_{1-x-y}Bi_{y}, in which z is between approximately 0.3 and 0.5, x is between approximately 0 and approximately 0.05, y is between approximately 0.01 and 0.05, and w is between approximately 0.01 and 0.05.

The materials described above may be deposited on a substrate through various deposition techniques known to those of skill in the art. For example, the photovoltaic materials may be deposited on a substrate through thin film epitaxial techniques, such as molecular beam epitaxy and metalorganic chemical vapor deposition, and other thin film techniques such as sputter deposition and evaporation.

A single junction solar cell may be constructed with a semiconductor alloy with intermediate bands, such as the AlGaNAs alloy described above, by depositing on a GaAs substrate an n-type layer of AlGaNAs alloy followed by a p-type layer of AlGaNAs. FIG. 5 is a block diagram illustrating a solar cell with first junction having an intermediate band according to one embodiment of the disclosure. A solar cell 500 may include a substrate 502 on which a photovoltaic absorber material 506 may be formed. The photovoltaic material 506 may include a p-type portion and an n-type portion to form a p-n junction to separate charges. The photovoltaic material 506 may be a dilute III-V semiconductor material, such as AlGaNAs described above. A blocking layer 504, such as AlGaAs, may be formed on the substrate 502, between the substrate 502 and the photovoltaic material 506, to electrically isolate the intermediate band of the photovoltaic material 506. A second blocking layer 508 may be formed on the photovoltaic material 506 to further electrically isolate the intermediate band. A contact 512 and a contact 514 may be formed on the blocking layer 508 and the substrate 502, respectively. A voltage develops across the contacts 512 and 514 when light impinges on the solar cell 500.

Although only a single junction is shown, multiple junctions may be present in the solar cell 500 by forming additional photovoltaic materials on the substrate 502 and/or the photovoltaic material 506. For example, additional conventional photovoltaic materials may be deposited on the photovoltaic material 506 to achieve improved solar absorption efficiency. In another example, additional photovoltaic materials with intermediate sub-bands, such as the alloys described above, may be formed on the photovoltaic material 506. The additional photovoltaic materials with intermediate sub-bands may be formed on the solar cell 500 to further improve solar absorption efficiency. That is, the additional photovoltaic materials may contain different alloys or similar alloys with different impurity ratios, to create a range of intermediate sub-bands for absorbing a larger number of photons from light impinging on the solar cell 500. The intermediate sub-bands may be engineered to accept photons from the impinging light based on known qualities of the impinging light. In particular, if the impinging light is known to have a particular distribution of photon energies, the intermediate sub-bands may be engineered to match the photon energies of the impinging light.

The solar cell 500 of FIG. 5 may be part of an energy system for converting and transferring the captured electrical energy from impinging light to another location and/or another form for consumption. For example, the solar cell 500 may be coupled to a DC-AC converter to convert electrical energy generated by the solar cell 500 to a form of power for use by consumer devices. In another example, the solar cell 500 may be coupled to batteries, such as Lithium-ion batteries, Nickel-Metal Hydride (NiMH) batteries, and/or lead-acid batteries for later conversion by the DC-AC converter.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present invention, disclosure, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An intermediate band solar cell, comprising:
a substrate; and
a photovoltaic material formed on the substrate, wherein the photovoltaic material comprises a III-V semiconductor alloy having intermediate energy bands, the photovoltaic material comprising an AlGaAsN alloy.

2. The intermediate band solar cell of claim 1, in which the substrate comprises at least one of GaAs and Si.

3. The intermediate band solar cell of claim 2, further comprising a blocking layer between the substrate and the photovoltaic material.

4. The intermediate band solar cell of claim 3, in which the photovoltaic material comprises a first p-type portion and a second n-type portion.

5. The intermediate band solar cell of claim 1, wherein the photovoltaic material comprises AlₓGa₁₋ₓN_{y}As_{1-y}, wherein x is between approximately 0.3 and approximately 0.5 and y is between approximately 0 and approximately 0.05.

6. The intermediate band solar cell of claim 1, wherein the photovoltaic material comprises Al_{z}Ga_{1-z}As_{1-x-y}NₓSb_{y}.

7. The intermediate band solar cell of claim 1, wherein the photovoltaic material comprises AlInGaNAsBi.

8. An apparatus, comprising:
a first junction comprising a first material and a second material,
wherein the first material and the second material comprise a III-V semiconductor alloy with an intermediate energy band, the first and the second material comprising an AlGaAsN alloy, and
wherein the first material is p-type and the second material is n-type.

9. The apparatus of claim 8, further comprising a substrate comprising at least one of GaAs and Si, wherein the first junction is deposited on the substrate.

10. The apparatus of claim 9, further comprising a blocking layer between the substrate and the first junction.

11. The apparatus of claim 8, wherein the first material comprises AlₓGa_{1-X}N_{y}As_{1-y}, wherein x is between approximately 0.3 and approximately 0.5 and y is between approximately 0 and approximately 0.05.

12. The apparatus of claim 8, wherein the first material comprises Al_{z}Ga_{1-z}As_{1-x-y}NₓSb_{y}.

13. The apparatus of claim 8, wherein the first material comprises AlInGaNAsBi.

14. A method, comprising:
forming a photovoltaic material on a substrate,
wherein forming the photovoltaic material comprises forming a photovoltaic material with an impurity to split a conduction band of the photovoltaic material into two intermediate sub-bands,
wherein forming the photovoltaic material comprises forming an AlGaAsN alloy.

15. The method of claim 14, wherein the step of forming the photovoltaic material comprises forming an AlGaAs alloy on a GaAs substrate.

16. The method of claim 15, further comprising forming a blocking layer on the substrate before forming the photovoltaic material on the substrate.

17. The method of claim 15, wherein the step of forming the photovoltaic material comprises:
forming a p-type photovoltaic material; and
forming a second n-type photovoltaic material.

18. The method of claim 14, wherein the step of forming the photovoltaic material comprises forming AlₓGa₁₋ₓN_{y}As_{1-y}, wherein x is between approximately 0.3 and approximately 0.5 and y is between approximately 0 and approximately 0.05.

19. The method of claim 14, wherein the step of forming the photovoltaic material comprises forming a lattice-matched photovoltaic material alloy comprising at least one of AlGaAsNSb and AlInGaNAsBi.
